(19) United States
(12) Patent Application Publication
(10) Pub. No.: US 2026/0266594 A1
(43) Pub. Date: Sep. 10, 2026

(54) Displacement sensing

(71) Applicant: UNM RAINFOREST INNOVATIONS, Albuquerque, NM (US)

(72) Inventor: Jean-Claude DIELS, Albuquerque, NM (US)

(73) Assignee: UNM RAINFOREST INNOVATIONS, Albuquerque, NM (US)

(21) Appl. No.: 19/559,143

(22) Filed: Mar. 6, 2026

Related U.S. Application Data
(60) Provisional application No. 63/768,618, filed on Mar. 7, 2025.

(51) Int. Cl. G01B 11/14; G01B 9/02003; G02F 1/355; G02F 1/377; G02F 1/39; H01S 3/00; H01S 3/108

(52) U.S. Cl. CPC G01B 11/14; G01B 9/02003; G02F 1/3558; G02F 1/3775; G02F 1/395; H01S 3/0092; H01S 3/1083

(57) ABSTRACT

An on-chip displacement sensor and method of displacement sensing is disclosed. The on-chip displacement sensor includes a pump laser configured to provide a plurality of pump laser beam pulses; a second-harmonic generator configured to receive the plurality of pump laser beam pulses and to produce modified pump laser beam pulses for each of the plurality of pump laser beam pulses; an optical parametric oscillator cavity of twice a length of a pump laser cavity of the pump laser, wherein the optical parametric oscillator cavity includes an optical parametric generator and an interferometer, wherein the on-chip displacement sensor further includes a first detector, an amplifier and divider, and a second detector configured to receive and to detect an interference of two signal pulses circulating in the optical parametric oscillator cavity via the interferometer.

### CROSS REFERENCE TO RELATED APPLICATIONS

This application claims priority to U.S. Provisional Patent Application No. 63/768,618 filed on Mar. 7, 2025, the contents of which are hereby incorporated by reference in its entirety.

### BACKGROUND

Measurement of displacement with an exceptional sub-femtometer resolution has been demonstrated using discrete and separate components using intracavity interferometry to detect changes in a length of one arm of the interferometer versus the other arm.

In order to apply this method to the measurement of a displacement, it is necessary to divert the reference and signal pulse to distinct branches of an intracavity interferometer. Even better accuracy can be achieved by miniaturization with integrated optics.

### SUMMARY

According to examples of the present disclosure, a sensor is disclosed that comprises an Optical Parametric Oscillator (OPO) on a chip, with a cavity in which two ultrashort pulses circulate, and are split into a reference arm and a signal arm. With the reference arm kept rigid, bending of the signal arm causes a small change in length of the corresponding cavity, hence a shift in optical frequency. By interfering the reference and (shifted) signal on a detector, one obtains the beat note at a frequency proportional to the displacement. Since the signal and reference circulate at only a few ps interval in the OPO, the 1/f noise is very small.

The accuracy of integrated optics technology makes it possible to create the cavity with the desired spit. Since the response Av to a displacement ΔL is inversely proportional to the cavity size L, an integrated optics implementation will provide 2 orders of magnitude faster response for quantum noise limited sensitivity to 0.1 fm. This implies that a 100 kHz signal of 10 pm amplitude could be detected in real time. According to examples of the present disclosure, an ultrasensitive displacement sensor comprises waveguides in the OPO section that are etched into lithium niobate on a Si/SiO2/LiNbO₃ wafer. The lithium niobate is x cut with the z axis perpendicular to the direction of propagation of light through the PPLN sections, which can be further modified/adapted to include waveguide dispersion.

A high frequency comb serves as pump to the OPO on a chip. The OPO cavity, terminated by Bragg reflectors, is twice the length of the pump cavity, such that two OPO pulses circulate. Every other pulse is diverted by a Mach Zehnder modulator to another branch at one cavity end. One branch is a reference. The length the other branch is modulated by the signal to be measured, namely a displacement along z of an inertial mass causing a bending about the x axis. The switch between reference and signal arms is realized by detecting and amplifying the signal from the reference arm and applying it to the Mach Zehnder with an OPO cavity length delay, such that the next pulse will be diverted to the signal arm.

In some examples, there are two PPLN sections in the pump waveguide. The first one is to generate the second harmonic of the pump comb. The reasons to choose the second harmonic are (i) the sensitivity in inversely proportional to the wavelength; (ii) to isolate the comb source from reflections that would perturb the pump mode-locking; and (iii) to improve the contrast between pulse peak and background.

The pump comb can be made by a microrig or an electro-optic comb generator; be integrated on the same chip (ideal) or fiber coupled. The pump comb needs to have a repetition rate a even multiple of the OPO Free Spectral Range, in order to have two (or more) pulses circulating in the cavity.

The present sensors can be used in a variety of applications: With the addition of an inertial mass (which could be minuscule) this can be an ultrasensitive accelerometer. A combination of 9 of these with common pump can become a complete inertial navigational instrument, without the need for gyroscopes. It can be used to monitor deformations of critical structures, detect acoustic waves, etc. A pair of these sensors with the same pump laser can be elements of a gravitational wave detector, by detecting the relative motion of two gravitational wave sensing mirrors.

An ultrasensitive sensor on a chip comprising an integrated optical circuit on a chip comprising a pump laser and an optical parametric oscillator (OPO) comprising a periodically poled lithium niobate gain medium coupled to a waveguide linear cavity terminated on one side by a first reflector and on the other side by two branches terminated by two reflectors. The OPO cavity length is an even multiple of the pump cavity length. The pump is external and coupled to the chip via a fiber. Each of two pulses circulating in the OPO is diverted alternatively on one of the two branches by a Mach Zehnder modulator, the latter being driven by a diode detecting the optical pulse in one of the branches. One of the branches is a reference arm, the other a signal arm. The two pulses are extracted from the OPO and made to interfere on a detector via a Mach Zehnder interferometer, creating a beat signal at a frequency proportional to the length difference between the two branches. An optical path change is produced by bending the chip. The bending is produced by attaching an inertial mass to the end of the signal branch. The ultrasensitive sensor is used for inertial navigation, sonar detection, a seismograph, or an accelerometer. The ultrasensitive sensor detects displacements or magnetic fields. A combination of nine ultrasensitive sensor on a chip with a common pump laser, each with an inertial mass, disposed in a geometry to provide complete motion (rotation-translation) information for inertial navigation. The signal reflector is outside the chip. A pair ultrasensitive sensor on a chip with common pump, wherein the signal reflector is outside the chip, disposed to detect gravitational waves.

According to examples of the present disclosure, a on-chip displacement sensor is disclosed that comprises a substrate; one or more layers formed on a top surface of the substrate; a pump laser formed in the one or more layers and configured to provide a plurality of pump laser beam pulses; a second-harmonic generator formed in the one or more layers and configured to receive the plurality of pump laser beam pulses and to produce modified pump laser beam pulses for each of the plurality of pump laser beam pulses; an optical parametric oscillator cavity of twice a length of a pump laser cavity of the pump laser formed in the one or more layers, wherein the optical parametric oscillator cavity comprises: an optical parametric generator that receives two successive modified pump laser beam pulses during a round-trip time of the optical parametric cavity, each of the two successive modified pump laser beam pulses creating successive optical pulses at frequency ωₛ separated by an optical parametric oscillator cavity length or separated in time by half of an optical parametric oscillator cavity round-trip time, wherein a first of the plurality of the modified pump laser beam pulses is split into a first optical signal pulse at frequency ωₛ and a second optical signal pulse at frequency op; an interferometer comprising first interferometer reflector at an end of a reference arm and second interferometer reflector at an end of a sensor arm, wherein the interferometer receives the first optical signal pulse at frequency ωₛ and reflects back through the first interferometer reflector the first optical signal pulse at frequency ωₛ that reaches an end of the optical parametric oscillator cavity at a reflector when the second optical signal pulse at frequency ωₛ has been sent to the sensor arm by an optical switch and reaches the second interferometer reflector, wherein the on-chip displacement sensor further comprises: a first detector configured to receive and detect the second optical signal pulse and to produce a synchronization signal for the optical switch; an amplifier and divider by two connected to the first detector and configured to receive the first detection signal and to produce an amplified detection signal to the optical switch and to control operations of the optical switch based on the amplified detection signal; and a second detector configured to receive and to detect an interference of two signal pulses circulating in the optical parametric oscillator cavity via the interferometer. The second-harmonic generator and the optical parametric generator can comprise periodically poled lithium niobate. The one or more layers can comprise a silicon dioxide layer formed on a top surface of the substrate and a lithium niobate layer formed on a top surface of the silicon dioxide layer. The lithium niobate layer is x cut with a z axis perpendicular to a direction of propagation of the optical signal pulse through the first nonlinear optical parametric element and the second nonlinear optical parametric element. The pump laser beam pulses can be produced by a high frequency comb that is formed on the lithium niobate layer. The optical path length change is caused by a bend experienced by the substrate. The pump wavelength of the pump laser beam can be 1560 nm and the modified laser beam pulses can have a wavelength of 780 nm. The pump laser produces the pump laser beam pulses with a frequency op that generates a gain for a signal frequency ωₛ and an idler of frequency ωᵢ such that ωₚ=ωₛ+ωᵢ where only ωₛ is resonant in the optical parametric oscillator cavity.

According to examples of the present disclosure, a displacement sensor is disclosed that comprises a silicon substrate; a silicon dioxide layer formed on a top surface of the silicon substrate; a lithium niobate layer formed on a top surface of the silicon dioxide layer; a first waveguide formed in the lithium niobate layer and comprising a first nonlinear optical element that is configured to receive a pump laser beam having a pump wavelength at a first waveguide end and configured to modify the pump laser beam to a first pump laser beam pulse with a first wavelength and configured to transmit the first pump laser beam pulse at a second waveguide end; a second waveguide formed in the lithium niobate layer and connected to the first waveguide and configured to receive the first pump laser beam pulse at a third waveguide end and comprising a second nonlinear optical element that is configured to modify the first laser beam pulse to a second pump laser beam pulse with a second wavelength and configured to transmit the second pump laser beam pulse at a fourth waveguide end and configured to reflect the second laser pulse based on an interface between the first waveguide and the second waveguide; a third waveguide configured direct the second laser pulse that is reflected to a first reflector that reflects the second laser pulse back through the third waveguide and through the second nonlinear optical element; a fourth waveguide; an optical switch; an interferometer formed in the lithium niobate layer and controlled by the optical switch and comprising a reference arm comprising a second reflector at a reference arm end and a sensor arm comprising a third reflector at a sensor arm end and configured to receive the second laser bean pulse from the fourth waveguide and based on a second beam pulse reflected path and a second beam pulse transmission path; a detector configured to detect an optical path length change in the sensor arm of the interferometer as measured by a beat frequency between the second laser beam pulse in the second beam pulse reflected path and the second beam pulse transmission path; and an amplifier connected to the detector and the optical switch and configured to amplify a detection signal from the detector and to control operations of the optical switch based on the detection signal. The first nonlinear optical element and the second nonlinear optical element can comprise periodically poled lithium niobate. The lithium niobate layer can be x cut with a z axis perpendicular to a direction of propagation of first laser beam pulse and the second laser beam pulse through the first nonlinear optical parametric element and the second nonlinear optical parametric element. The pump laser beam can be produced by a high frequency comb that is formed on the lithium niobate layer. The optical path length change is caused by a bend experienced by the silicon substrate. The pump wavelength of the pump laser beam is 1560 nm and the first wavelength is 780 nm.

According to examples of the present disclosure, a method of on-chip displacement sensing is disclosed that comprises providing a plurality of pump laser beam pulses by a pump laser that formed in one or more layers on top a substrate; receiving the plurality of pump laser beam pulses and producing modified pump laser beam pulses for each of the plurality of pump laser beam pulses by a second-harmonic generator that is formed in the one or more layers; receiving the modified pump laser beam pulses by an optical parametric oscillator cavity of twice a length of a pump laser cavity of the pump laser that is formed in the one or more layers, wherein the optical parametric oscillator cavity comprises an optical parametric oscillator, a reflector, an interferometer that comprises a first interferometer reflector at an end of a reference arm and a second interferometer reflector at an end of a sensor arm that is controlled by an optical switch, wherein the method further comprises: receiving two successive modified pump laser beam pulses during a round-trip time of the optical parametric cavity, each of the two successive modified pump laser beam pulses creating successive optical pulses at frequency ωₛ separated by an optical parametric oscillator cavity length or separated in time by half of an optical parametric oscillator cavity round-trip time, wherein a first of the plurality of the modified pump laser beam pulses is split into a first optical signal pulse at frequency ωₛ and a second optical signal pulse at frequency op; receiving, by the interferometer, the first optical signal pulse at frequency ωₛ and reflects back through the first interferometer reflector the first optical signal pulse at frequency ωₛ that reaches an end of the optical parametric oscillator cavity at a reflector when the second optical signal pulse at frequency ωₛ has been sent to the sensor arm by an optical switch and reaches the second interferometer reflector; receiving and detecting, by the first detector, the second optical signal pulse and to produce a synchronization signal for the optical switch; amplifying and dividing by two, by the amplifier that is connected to the first detector, the synchronization signal and to produce an amplified detection signal to the optical switch and controlling operations of the optical switch based on the amplified detection signal; and receiving and detecting, by the second detector, an optical path length change in the sensor arm of the interferometer as measured by a beat frequency produced by the interferometer. The second-harmonic generator and the optical parametric oscillator can comprise periodically poled lithium niobate. The one or more layers can comprise a silicon dioxide layer formed on a top surface of the substrate and a lithium niobate layer formed on a top surface of the silicon dioxide layer. The lithium niobate layer can be x cut with s z axis perpendicular to a direction of propagation of first laser beam pulse and the second laser beam pulse through the first nonlinear optical parametric element and the second nonlinear optical parametric element. The pump laser beam can be produced by a high frequency comb that is formed on the lithium niobate layer. The optical path length change is caused by a bend experienced by the substrate.

### BRIEF DESCRIPTION OF THE FIGURES

The above and/or other aspects and advantages will become more apparent and more readily appreciated from the following detailed description of examples, taken in conjunction with the accompanying drawings, in which:

FIG. 1 shows a prior art displacement system from Xiaobing Zhu, Matthias Lenzner, and Jean-Claude Diels. Phase nanoscopy with correlated frequency combs. Sensors, 23:301, 2023;

FIG. 2 shows a first displacement sensor according to examples of the present disclosure;

FIG. 3A, FIG. 3B, FIG. 3C, FIG. 3D, and FIG. 3E show a second displacement sensor at successive time intervals according to the examples of the present disclosure;

FIG. 4 shows an accelerometer according to examples of the present disclosure; and

FIG. 5 shows a method for displacement sensing according to examples of the present disclosure.

### DETAILED DESCRIPTION

Reference will now be made in detail to the present teachings, examples of which are illustrated in the accompanying drawings. In the drawings, like reference numerals have been used throughout to designate identical elements. In the following description, reference is made to the accompanying drawings that form a part thereof, and in which is shown by way of illustration specific examples of practicing the present teachings. The following description is, therefore, merely exemplary.

Most sensors are based on measuring a phase by the amplitude of interfering beams.

Highest resolution can be achieved by performing directly a phase measurement inside a mode-locked laser cavity. A high photon number (N) allows for a much smaller phase uncertainty according to [symbol] = [symbol] ≥½. Two pulses—a reference and a signal—are circulated in an active cavity, creating two correlated frequency combs. By modifying the phase of the signal relative to that of the reference by Δφ (for instance with an electro-optic phase modulator), the signal comb is frequency shifted by Δv=Δφ/(2πτTₚ)=vΔL/L (where rₚ is the round-trip time of the cavity of length L, v the optical frequency, and ΔL the optical path change corresponding to Δφ). The frequency recorded by beating the two combs is a measure of the phase probed by the signal. The phase shift corresponds to an optical path change of 0.07 femtometer. These results were obtained by a Optical Parametric Oscillator (OPO) synchronously pumped by a mode-locked Ti:sapphire laser.

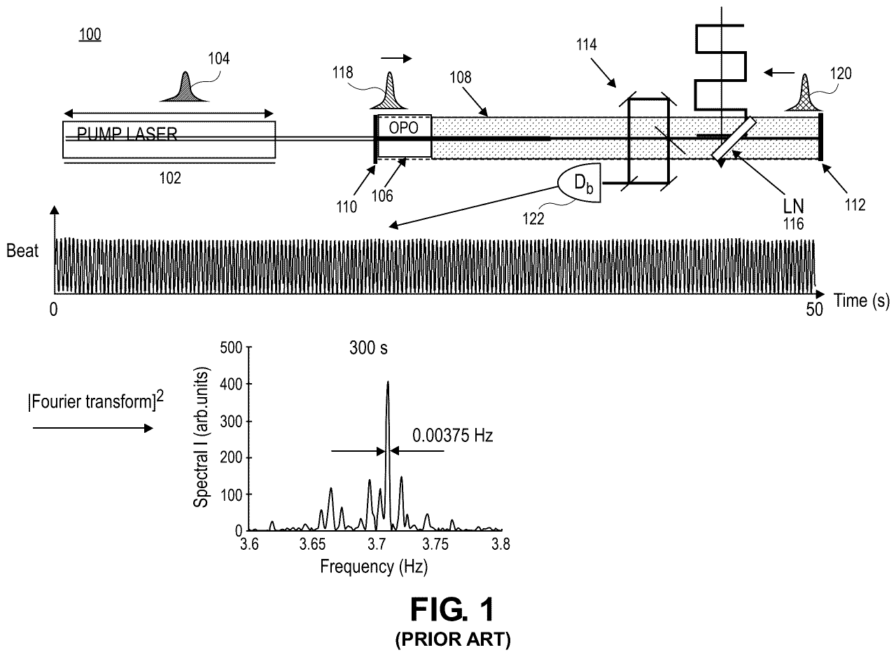

FIG. 1 shows a prior art displacement system 100. An external pump laser 102 produces a pump laser beam pulse 104 that is received by an optical parametric oscillator 106 within a resonant cavity 108 bounded by a first mirror 110 and a second mirror 112. The resonant cavity 108 also includes an interferometer 114 and a reflector 116. The resonant cavity 108 typically has a length of more than one meter and up to two meters or more depending on the configuration. The optical parametric oscillator 106 converts the pump laser 104 to a first laser beam pulse 118 with a small wavelength than the pump laser beam pulse 104. The first laser beam pulse 118 is partially transmitted by the interferometer 114, is partially reflected by the lithium niobate crystal 116, and is then reflected back through the resonant cavity 108 by the second mirror 112 to produce a second laser beam pulse 120. A detector 122 detects beats produced by the first laser pulse 118 and the second laser pulse 120, as shown in the plot below the conventional displacement system 100. A Fourier transform is shown below the plot of the beats, which shows a width of peak frequence of the beats as 0.00375 Hz.

In the below examples, the pump laser can be an electro-optic comb laser that generates a highly stable, wide-bandwidth optical frequency combs by modulating a continuous-wave seed laser with radio-frequency signals using lithium niobate modulators. The pump laser is chosen to match an optical parametric oscillator. The pump laser is denoted by the subscript p, and is characterized by a frequency of ωₚ, such that ωₚ=ωₛ+wᵢ≈2ωₛ and ωₚ=2πc/λₚ. The optical parametric oscillator converts the pump laser with frequency op into two output pulses at lower frequency (a), a)) by a second-order nonlinear optical interaction. As noted above, the sum of the output laser pulses' frequencies is equal to the input pulse frequency: ωₚ=ωₛ+ωᵢ, where the subscript s denotes a pulse called “signal” and the subscript i denotes a pulse called “idler,” where the pulse with the higher frequency is the “signal.” In the degenerate optical parametric oscillator case, the output frequency is one-half the pump frequency, ωₛ=ωᵢ=ωₚ/2, which results in half-harmonic generation when the signal and idler have the same polarization.

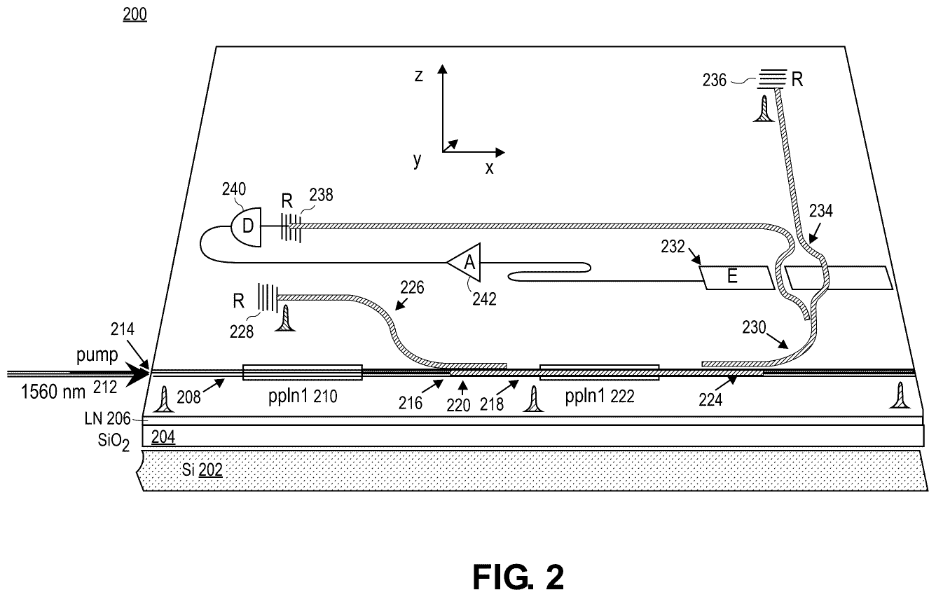

FIG. 2 shows a first displacement sensor 200 according to examples of the present disclosure. The first displacement sensor 200 according to examples of the present disclosure comprise a substrate layer 202, such as a silicon substrate layer. A second layer 204, such as a silicon dioxide layer, is formed on a top surface of the substrate 202. A further layer 206, such as a lithium niobate layer, is formed on a top surface of the second layer 204.

The first displacement sensor 200 comprises a first waveguide 208 formed in the further layer 206, such as the lithium niobate layer. The first waveguide 208 comprises a first nonlinear optical element 210 that is configured to receive a pump laser beam 212 having a pump wavelength at a first waveguide end 214 and configured to modify the pump laser beam 212 to a first pump laser beam pulse with a first wavelength and configured to transmit the first pump laser beam pulse at a second waveguide end 216. For example, the first nonlinear optical element 210 can comprise periodically poled lithium niobate. Other suitable nonlinear optical materials can also be used. In some examples, the pump laser beam is produced by a high frequency comb that is formed on the further layer 206, such as the lithium niobate layer.

The first displacement sensor 200 also comprises a second waveguide 218 formed in the further layer 206, such as the lithium niobate layer. The second waveguide 218 is connected to or coupled with the first waveguide 208. The second waveguide 218 is configured to receive the first pump laser beam pulse at a third waveguide end 220. The second waveguide 218 comprises a second nonlinear optical element 222 that is configured to modify the first laser beam pulse to a second pump laser beam pulse with a second wavelength and configured to transmit the second pump laser beam pulse at a fourth waveguide end 224 and configured to reflect the second laser pulse based on an interface between the first waveguide and the second waveguide. For example, the second nonlinear optical element 222 can comprise periodically poled lithium niobate. Other suitable nonlinear optical materials can also be used.

The first displacement sensor 200 also comprises a third waveguide 226 that is configured direct the second laser pulse that is reflected to a first reflector 228 that reflects the second laser pulse back through the third waveguide 226 and through the second nonlinear optical element 222. In some examples the first reflector 228 is a Bragg reflector. Other suitable optical reflectors can also be used. The first displacement sensor 200 also comprises a fourth waveguide 230, an optical switch 232, and an interferometer 234. For example, the optical switch 232 is a Mach Zehnder amplitude modulator. The optical switch 232 is configured to direct the second laser pulse into the different arms of the interferometer 234.

The interferometer 234 is formed in the further layer 206, such as the lithium niobate layer, and can be controlled by the optical switch 232. The interferometer 234 comprises a reference arm comprising a second reflector 236 at a reference arm end and a sensor arm comprising a third reflector 238 at a sensor arm end and configured to receive the second laser bean pulse from the fourth waveguide 230 and based on a second beam pulse reflected path and a second beam pulse transmission path. In some examples, the second reflector 236 and the third reflector 238 can be Bragg reflectors. Other suitable optical reflectors can also be used.

The first displacement sensor 200 also comprises a detector 240 configured to detect an optical path length change in the sensor arm of the interferometer as measured by a beat frequency between the second laser beam pulse in the second beam pulse reflected path and the second beam pulse transmission path.

The first displacement sensor 200 also comprises an amplifier 242 connected to the detector 240 and the optical switch 232 and configured to amplify a detection signal from the detector 240 and to control operations of the optical switch 232 based on the detection signal.

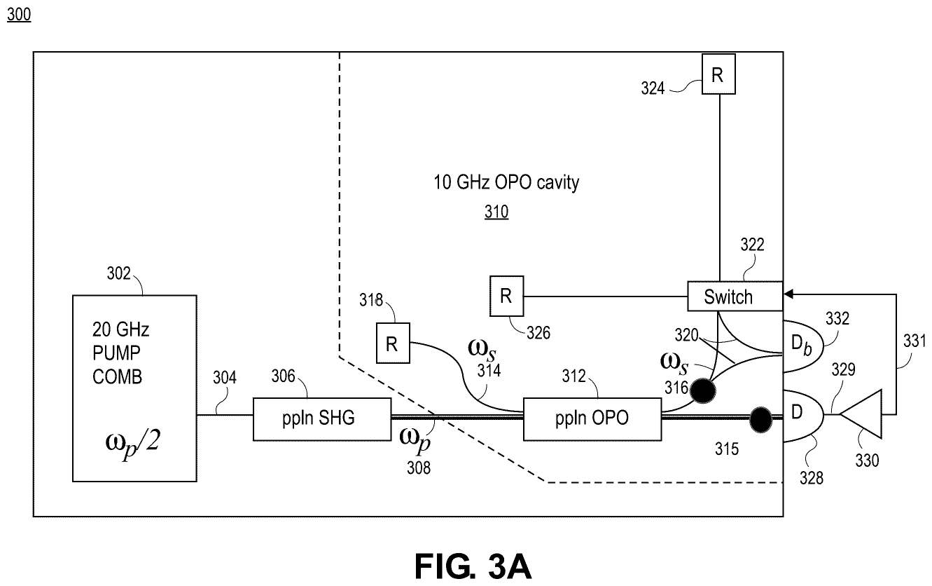

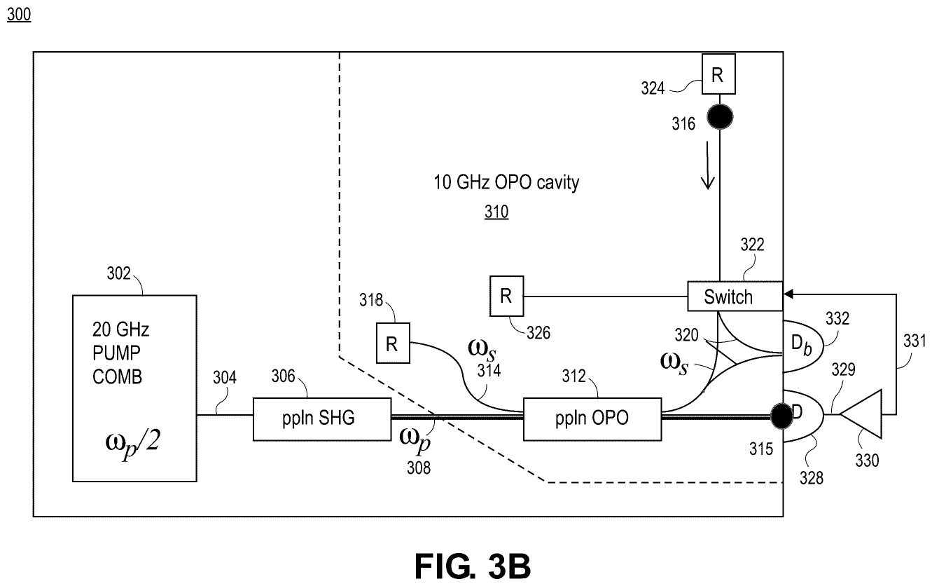

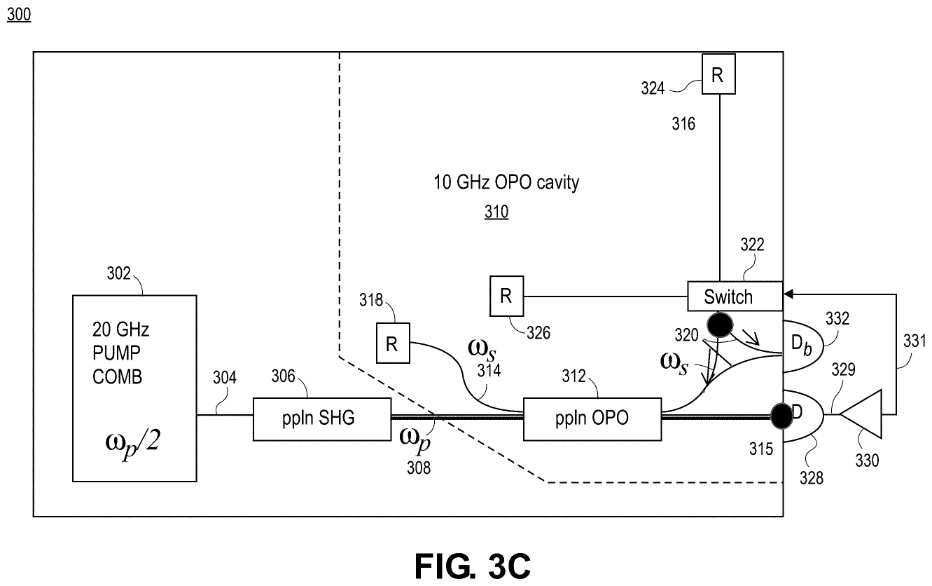

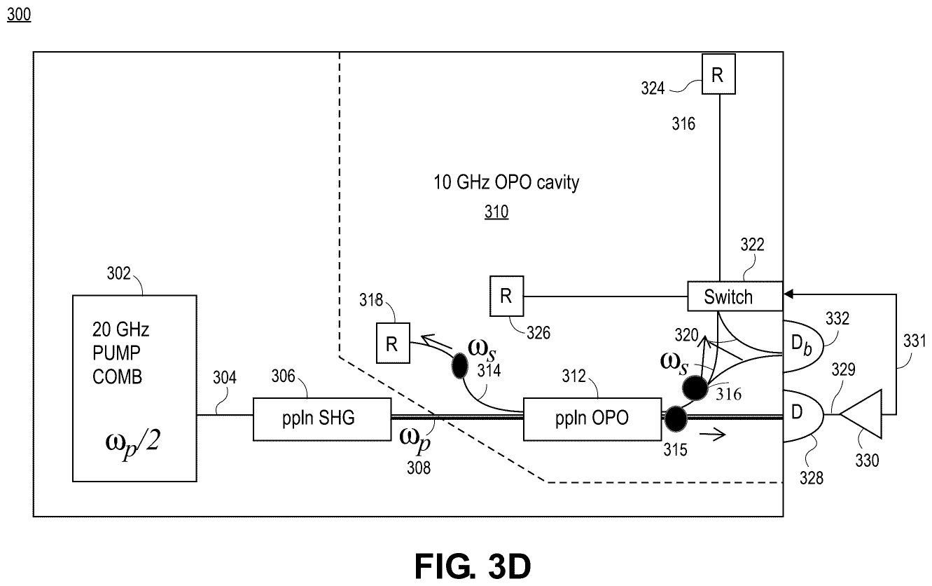

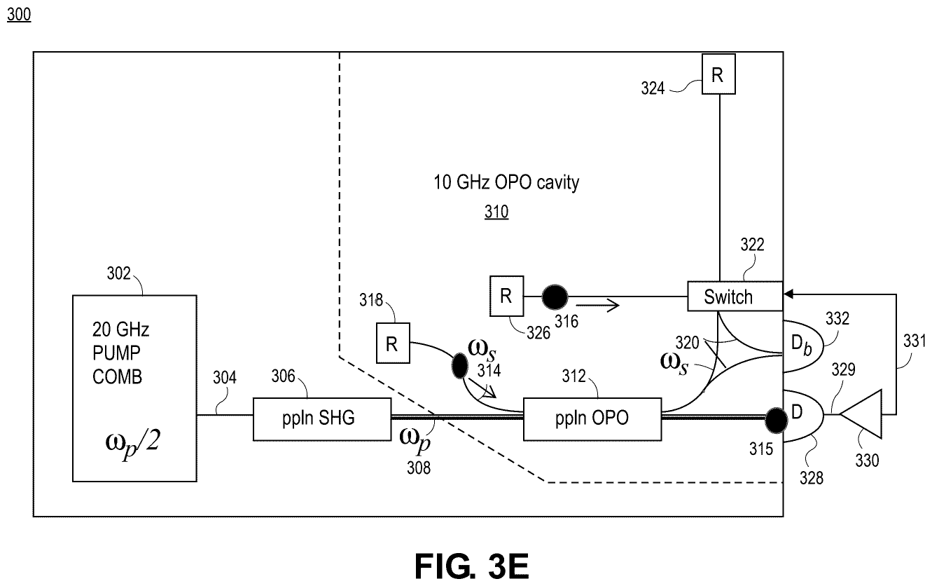

FIG. 3A, FIG. 3B, FIG. 3C, FIG. 3D, and FIG. 3E show a second displacement sensor 300 at successive time intervals showing progression of the light signal pulses through the sensor components according to the examples of the present disclosure. The second displacement sensor 300 is an on-chip displacement sensor that comprises a substrate and one or more layers formed on a top surface of the substrate, such as shown and described in FIG. 2. The variously described components of the second displacement sensor 300 are connected or coupled by one or more optical waveguides that provide pathways for the various optical signals to be transmitted on the chip. The one or more waveguides can be represented by the various lines or curves connecting the elements on the second displacement sensor 300.

The second displacement sensor 300 comprises a pump laser 302 formed in the one or more layers and configured to provide a plurality of pump laser beam pulses 304. In some examples, the pump laser beam 304 is produced by a high frequency comb that is formed on the further layer 206, such as the lithium niobate layer. For example, the pump laser beam can be produced by a 20 GHz pump comb with a with a frequency represented by ωₚ/2.

The second displacement sensor 300 also comprises a second-harmonic generator 306 formed in the one or more layers and configured to receive the plurality of pump laser beam pulses 304 and to produce modified pump laser beam pulses 308 with a frequency represented by op for each of the plurality of pump laser beam pulses 304. In some examples, the second-harmonic generator and/or the optical parametric oscillator comprise periodically poled lithium niobate.

The second displacement sensor 300 also comprises an optical parametric oscillator cavity 310 formed in the one or more layers. The optical parametric oscillator cavity 310 is twice a length of a pump laser cavity of the pump laser 302. The optical parametric oscillator cavity 310 can comprise an optical parametric generator 312 that receives two successive modified pump laser beam pulses 308 during a round-trip time of the optical parametric cavity 310, each of the two successive modified pump laser beam pulses 308 creating successive optical pulses at frequency ωₛ 316 separated by an optical parametric oscillator cavity length or separated in time by half of an optical parametric oscillator cavity round-trip time, wherein a first of the plurality of the modified pump laser beam pulses 308 is split into a first optical signal pulse at frequency ωₛ 316 and a second optical signal pulse at frequency op 315.

In some examples, the pump laser 302 produces the pump laser beam 304 with a frequency op that generates a gain for a signal frequency ωₛ and an idler of frequency ωᵢ such that ωₚ=ωₛ+ωᵢ where only ωₛ is resonant in the optical parametric oscillator cavity. In some examples, the second-harmonic generator and/or the optical parametric oscillator comprise periodically poled lithium niobate.

The optical parametric oscillator cavity 310 also comprises an interferometer 320 comprising first interferometer reflector 326 at an end of a reference arm and second interferometer reflector 324 at an end of a sensor arm, wherein the interferometer 320 receives the first optical signal pulse at frequency ωₛ 316 and reflects back through the first interferometer reflector 326 the first optical signal pulse at frequency ωₛ 316 that reaches an end of the optical parametric oscillator cavity 310 at a reflector 318 when the second optical signal pulse at frequency ωₛ 316 has been sent to the sensor arm by an optical switch 322 and reaches the second interferometer reflector 324.

The optical parametric oscillator cavity 310 also comprises the optical switch 322 configured to send alternatively the optical signal pulse 316 into a reference arm comprising an end cavity reflector 324 and a sensor arm comprising an end cavity reflector 326 of an interferometer 320.

The optical parametric oscillator cavity 310 also comprises a reflector 318 configured to reflect the optical signal pulse 316 back to and through the optical parametric generator 312.

The second displacement sensor 300 also comprises a first detector 328 configured to receive and detect the pump laser beam pulse 308 and to produce a synchronization signal 329 for the optical switch 322.

The second displacement sensor 300 can comprise an amplifier and divider by two 330 connected to the first detector 328 and configured to receive the synchronization signal 329 and to produce an amplified detection signal 331 to the optical switch 322 and to control operations of the optical switch 322 based on the amplified detection signal 331.

The second displacement sensor 300 can comprise a second detector 332 configured to receive and to detect an interference (beat note signal) of the two signal pulses circulating in the optical parametric oscillator cavity 310 via the interferometer 320. The beat note can be characterized by the equation

$$Δυ = υ \frac{Δ L}{L} = \frac{Δφ}{2 π {τ}_{p}} .$$

The present arrangements can provide at least 100 times improvement of the prior art of Δν if L→L/100. In the examples of the present disclosure, the optical parametric oscillator cavity can be around 2 cm in dimension.

In some examples, the one or more layers of the second displacement sensor 300 can comprise a silicon dioxide layer formed on a top surface of the substrate and a lithium niobate layer formed on a top surface of the silicon dioxide layer. The lithium niobate layer can be x cut with a z axis perpendicular to a direction of propagation of the optical signal pulse through the first nonlinear optical parametric element and the second nonlinear optical parametric element. The pump laser beam can be produced by a high frequency comb that is formed on the lithium niobate layer. The optical path length change as measured by the interferometer 320 is caused by a bend experienced by the substrate. In some examples, the pump wavelength of the pump laser beam 304 is 1560 nm and the wavelength of the modified pump laser beam pulse 308 is 780 nm.

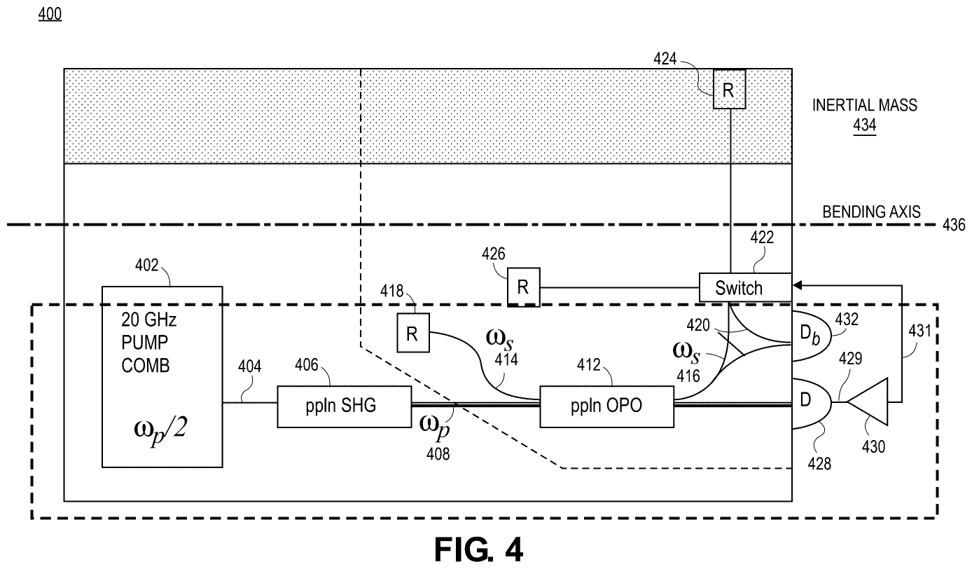

FIG. 4 shows an accelerometer 400 for displacement sensing according to examples of the present disclosure. The arrangement of the accelerometer 400 is similar to arrangement of the second displacement sensor 300. The accelerometer 400 is an on-chip displacement sensor that comprises a substrate and one or more layers formed on a top surface of the substrate, such as shown and described in FIG. 2. The variously described components of the accelerometer 400 are connected or coupled by one or more optical waveguides that provide pathways for the various optical signals to be transmitted on the chip. The one or more waveguides can be represented by the various lines or curves connecting the elements on the accelerometer 400.

The accelerometer 400 comprises a pump laser 402 formed in the one or more layers and configured to provide a pump laser beam 404. In some examples, the pump laser beam 404 is produced by a high frequency comb that is formed on the further layer 206, such as the lithium niobate layer. For example, the pump laser beam can be produced by a 20 GHz pump comb with a with a frequency represented by ωₚ/2.

The accelerometer 400 also comprises a second-harmonic generator 406 formed in the one or more layers and configured to receive the pump laser beam 404 and to produce a modified pump laser beam pulse 408 with a frequency represented by cop. In some examples, the second-harmonic generator 406 and/or the optical parametric oscillator comprise periodically poled lithium niobate.

The accelerometer 400 also comprises an optical parametric oscillator cavity 410 formed in the one or more layers. The optical parametric oscillator cavity 410 can comprise an optical parametric generator 312 that receives the modified pump laser beam pulse 408 and injects a first optical signal pulse at frequency ωₛ 416 and a second optical signal pulse 414 at frequency ωₛ 414 into an optical parametric oscillator cavity 410. In some examples, the pump laser 402 produces the pump laser beam 404 with a frequency op that generates a gain for a signal frequency ωₛ and an idler of frequency ωᵢ such that ωₚ=ωₛ+ωᵢ where only ωₛ is resonant in the optical parametric oscillator cavity. In some examples, the second-harmonic generator and/or the optical parametric oscillator comprise periodically poled lithium niobate.

The optical parametric oscillator cavity 410 can comprise an optical switch 422 configured to send alternatively the optical signal pulse 416 into a reference arm comprising an end cavity reflector 424 and a sensor arm comprising an end cavity reflector 426 of an interferometer 420.

The optical parametric oscillator cavity 410 can comprise a first reflector 424 or a second reflector 424 configured to reflect the optical signal pulse 416 back to and through the optical parametric generator 412 based on a configuration of the optical switch 422.

The optical parametric oscillator cavity 410 can comprise a third reflector 418 configured to reflect the optical signal pulse 416 back to and through the optical parametric generator 412.

The accelerometer 400 also comprises a first detector 428 configured to receive and detect the pump laser beam pulse 408 and to produce a synchronization signal 429 for the optical switch 422.

The accelerometer 400 can comprise an amplifier and divider by two 430 connected to the first detector 428 and configured to receive the first detection signal 429 and to produce an amplified detection signal 431 to the optical switch 422 and to control operations of the optical switch 432 based on the amplified detection signal 431.

The accelerometer 400 can comprise a second detector 432 configured to receive and to detect an interference (beat note signal) of the two signal pulses circulating in the optical parametric oscillator cavity 410 via the interferometer 420.

The accelerometer 400 comprises a bending axis 436, as shown by the dot-dash line in FIG. 4, that allows the substrate to flex about the bending axis 436. An internal mass is provided on one side of the bending axis 436, on which the reflector 424 is arranged. A bend or flex at the bending axis 436 results in a path length change for a signal pulse that is directed and reflected by the reflector 424 that is then detected by the detector 432. The degree of bend or flex can then be interpreted as a measure of acceleration of the bend or flex of the substrate.

In some examples, the one or more layers of the accelerometer 400 can comprise a silicon dioxide layer formed on a top surface of the substrate and a lithium niobate layer formed on a top surface of the silicon dioxide layer. The lithium niobate layer can be x cut with a z axis perpendicular to a direction of propagation of the optical signal pulse through the first nonlinear optical parametric element and the second nonlinear optical parametric element. The pump laser beam can be produced by a high frequency comb that is formed on the lithium niobate layer. The optical path length change as measured by the interferometer 420 is caused by a bend experienced by the substrate. In some examples, the pump wavelength of the pump laser beam 404 is 1560 nm and the wavelength of the modified pump laser beam pulse 408 is 780 nm.

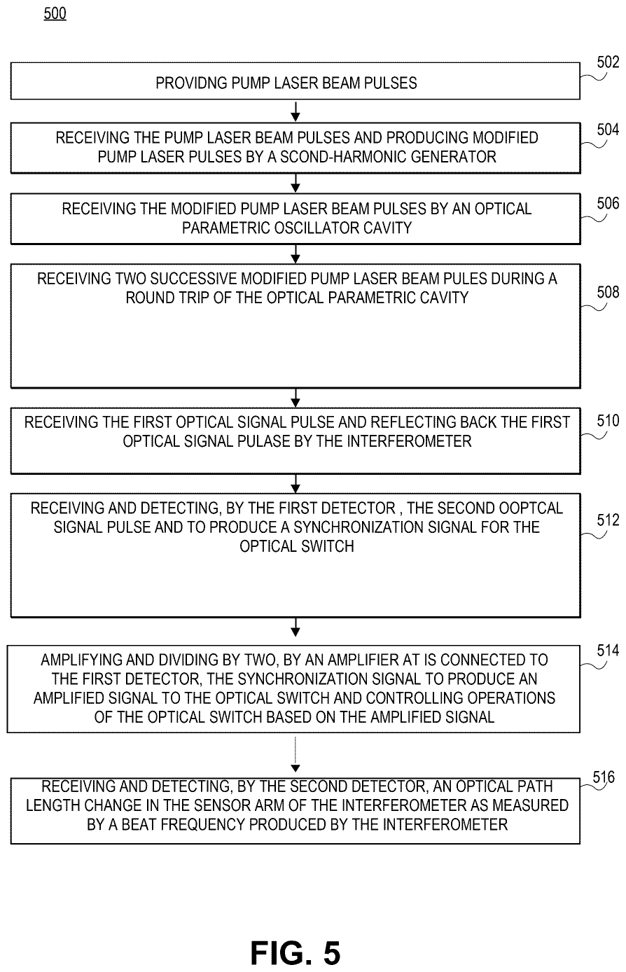

FIG. 5 shows a flowchart 500 of a method for on-chip displacement sensing. The method comprises providing a plurality of pump laser beam pulses 304, 404 by a pump laser 302, 402 that formed in one or more layers on top a substrate, as in 502.

The method continues by receiving the plurality of pump laser beam pulses 304, 404 and producing a modified pump laser beam pulses 308, 408 for each of the plurality of pump laser beam pulses by a second-harmonic generator 306, 406 that is formed in the one or more layers, as in 504.

The method continues by receiving the modified pump laser beam pulses 308, 408 by an optical parametric oscillator cavity 310, 410 of twice a length of a pump laser cavity of the pump laser 302, 402 that is formed in the one or more layers, wherein the optical parametric oscillator cavity 310, 410 comprises an optical parametric oscillator 312, 412, a reflector 318, 418, an interferometer 320, 420 that comprises a first interferometer reflector 326, 426 at an end of a reference arm and a second interferometer reflector 324, 424 at an end of a sensor arm that is controlled by an optical switch 322, 422 as in 506.

The method continues by receiving two successive modified pump laser beam pulses 308, 408 during a round-trip time of the optical parametric cavity 310, 410, each of the two successive modified pump laser beam pulses 308, 408 creating successive optical pulses at frequency ωₛ 316, 416 separated by an optical parametric oscillator cavity length or separated in time by half of an optical parametric oscillator cavity round-trip time, wherein a first of the plurality of the modified pump laser beam pulses 308 is split into a first optical signal pulse at frequency ωₛ 316, 416 and a second optical signal pulse at frequency op 315, as in 508.

The method continues by receiving, by the interferometer, the first optical signal pulse at frequency ωₛ 316, 416 and reflects back through the first interferometer reflector 326, 426 the first optical signal pulse at frequency ωₛ 316, 416 that reaches an end of the optical parametric oscillator cavity 310, 410 at a reflector 318, 418 when the second optical signal pulse at frequency ωₛ 316, 416 has been sent to the sensor arm by an optical switch 322, 422 and reaches the second interferometer reflector 324, 424, as in 510.

The method continues by receiving and detecting, by the first detector 328, 428, the second optical signal pulse and to produce a synchronization signal for the optical switch 322, 422, as in 512.

The method continues by amplifying and dividing by two, by the amplifier 330, 430 that is connected to the first detector 328, 428, the synchronization signal and to produce an amplified detection signal 331, 431 to the optical switch 322, 422 and controlling operations of the optical switch 322, 422 based on the amplified detection signal 331, 431, as in 514.

The method continues by receiving and detecting, by the second detector 332, 432 an optical path length change in the sensor arm of the interferometer as measured by a beat frequency produced by the interferometer 320, 420, as in 516.

Different examples of the apparatus(es) and method(s) disclosed herein include a variety of components, features, and functionalities. It should be understood that the various examples of the apparatus(es) and method(s) disclosed herein may include any of the components, features, and functionalities of any of the other examples of the apparatus(es) and method(s) disclosed herein in any combination, and all of such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Reference herein to “one example” means that one or more feature, structure, or characteristic described in connection with the example is included in at least one implementation. The phrase “one example” in various places in the specification may or may not be referring to the same example. As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Notwithstanding that the numerical ranges and parameters setting forth the broad scope of the embodiments are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −2, −3, −10, −20, −30, etc.

Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “one or more of”, for example, A, B, and C means any of the following: either A, B, or C alone; or combinations of two, such as A and B, B and C, and A and C; or combinations of A, B and C.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

Reference herein to “one example” means that one or more feature, structure, or characteristic described in connection with the example is included in at least one implementation. The phrase “one example” in various places in the specification may or may not be referring to the same example. As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “one or more of”, for example, A, B, and C means any of the following: either A, B, or C alone; or combinations of two, such as A and B, B and C, and A and C; or combinations of A, B and C.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompasses by the following claims.

What is claimed is:

1. A on-chip displacement sensor comprising:
a substrate;
one or more layers formed on a top surface of the substrate;
a pump laser formed in the one or more layers and configured to provide a plurality of pump laser beam pulses;
a second-harmonic generator formed in the one or more layers and configured to receive the plurality of pump laser beam pulses and to produce modified pump laser beam pulses for each of the plurality of pump laser beam pulses;
an optical parametric oscillator cavity of twice a length of a pump laser cavity of the pump laser formed in the one or more layers, wherein the optical parametric oscillator cavity comprises:
an optical parametric generator that receives two successive modified pump laser beam pulses during a round-trip time of the optical parametric cavity, each of the two successive modified pump laser beam pulses creating successive optical pulses at frequency ωₛ separated by an optical parametric oscillator cavity length or separated in time by half of an optical parametric oscillator cavity round-trip time, wherein a first of the plurality of the modified pump laser beam pulses is split into a first optical signal pulse at frequency ωₛ and a second optical signal pulse at frequency ωₚ;
an interferometer comprising first interferometer reflector at an end of a reference arm and second interferometer reflector at an end of a sensor arm, wherein the interferometer receives the first optical signal pulse at frequency ωₛ and reflects back through the first interferometer reflector the first optical signal pulse at frequency ωₛ that reaches an end of the optical parametric oscillator cavity at a reflector when the second optical signal pulse at frequency ωₛ has been sent to the sensor arm by an optical switch and reaches the second interferometer reflector;
wherein the on-chip displacement sensor further comprises:
a first detector configured to receive and detect the second optical signal pulse and to produce a synchronization signal for the optical switch;
an amplifier and divider by two connected to the first detector and configured to receive the synchronization signal and to produce an amplified detection signal to the optical switch and to control operations of the optical switch based on the amplified detection signal; and
a second detector configured to receive and to detect an interference of two signal pulses circulating in the optical parametric oscillator cavity via the interferometer.

2. The on-chip displacement sensor of claim 1, wherein the second-harmonic generator and the optical parametric generator comprise periodically poled lithium niobate.

3. The one-chip displacement sensor of claim 1, wherein the one or more layers comprise a silicon dioxide layer formed on a top surface of the substrate and a lithium niobate layer formed on a top surface of the silicon dioxide layer.

4. The on-chip displacement sensor of claim 3, wherein the lithium niobate layer is x cut with a z axis perpendicular to a direction of propagation of the optical signal pulse through the first nonlinear optical parametric element and the second nonlinear optical parametric element.

5. The on-chip displacement sensor of claim 3, wherein the pump laser beam is produced by a high frequency comb that is formed on the lithium niobate layer.

6. The on-chip displacement sensor of claim 1, wherein the optical path length change is caused by a bend experienced by the substrate.

7. The on-chip displacement sensor of claim 1, wherein the pump wavelength of the pump laser beam pulses is 1560 nm and the modified pump laser beam pulses have a wavelength of 780 nm.

8. The on-chip displacement sensor of claim 1, wherein the pump laser produces the pump laser beam with a frequency op that generates a gain for a signal frequency ωₛ and an idler of frequency ωᵢ such that ωₚ=ωₛ+ωᵢ where only ωₛ is resonant in the optical parametric oscillator cavity.

9. A displacement sensor comprising:
a silicon substrate;
a silicon dioxide layer formed on a top surface of the silicon substrate;
a lithium niobate layer formed on a top surface of the silicon dioxide layer;
a first waveguide formed in the lithium niobate layer and comprising a first nonlinear optical element that is configured to receive a pump laser beam having a pump wavelength at a first waveguide end and configured to modify the pump laser beam to a first pump laser beam pulse with a first wavelength and configured to transmit the first pump laser beam pulse at a second waveguide end;
a second waveguide formed in the lithium niobate layer and connected to the first waveguide and configured to receive the first pump laser beam pulse at a third waveguide end and comprising a second nonlinear optical element that is configured to modify the first laser beam pulse to a second pump laser beam pulse with a second wavelength and configured to transmit the second pump laser beam pulse at a fourth waveguide end and configured to reflect the second laser pulse based on an interface between the first waveguide and the second waveguide;
a third waveguide configured direct the second laser pulse that is reflected to a first reflector that reflects the second laser pulse back through the third waveguide and through the second nonlinear optical element;
a fourth waveguide;
an optical switch;
an interferometer formed in the lithium niobate layer and controlled by the optical switch and comprising a reference arm comprising a second reflector at a reference arm end and a sensor arm comprising a third reflector at a sensor arm end and configured to receive the second laser bean pulse from the fourth waveguide and based on a second beam pulse reflected path and a second beam pulse transmission path;
a detector configured to detect an optical path length change in the sensor arm of the interferometer as measured by a beat frequency between the second laser beam pulse in the second beam pulse reflected path and the second beam pulse transmission path; and
an amplifier connected to the detector and the optical switch and configured to amplify a detection signal from the detector and to control operations of the optical switch based on the detection signal.

10. The displacement sensor of claim 9, wherein the first nonlinear optical element and the second nonlinear optical element comprise periodically poled lithium niobate.

11. The displacement sensor of claim 9, wherein the lithium niobate layer is x cut with a z axis perpendicular to a direction of propagation of first laser beam pulse and the second laser beam pulse through the first nonlinear optical parametric element and the second nonlinear optical parametric element.

12. The displacement sensor of claim 9, wherein the pump laser beam is produced by a high frequency comb that is formed on the lithium niobate layer.

13. The displacement sensor of claim 9, wherein the optical path length change is caused by a bend experienced by the silicon substrate.

14. The displacement sensor of claim 9, wherein the pump wavelength of the pump laser beam is 1560 nm and the first wavelength is 780 nm.

15. A method of on-chip displacement sensing comprising:
providing a plurality of pump laser beam pulses by a pump laser that formed in one or more layers on top a substrate;
receiving the plurality of pump laser beam pulses and producing modified pump laser beam pulses for each of the plurality of pump laser beam pulses by a second-harmonic generator that is formed in the one or more layers;
receiving the modified pump laser beam pulses by an optical parametric oscillator cavity of twice a length of a pump laser cavity of the pump laser that is formed in the one or more layers, wherein the optical parametric oscillator cavity comprises an optical parametric oscillator, a reflector, an interferometer that comprises a first interferometer reflector at an end of a reference arm and a second interferometer reflector at an end of a sensor arm that is controlled by an optical switch, wherein the method further comprises:
receiving two successive modified pump laser beam pulses during a round-trip time of the optical parametric cavity, each of the two successive modified pump laser beam pulses creating successive optical pulses at frequency ωₛ separated by an optical parametric oscillator cavity length or separated in time by half of an optical parametric oscillator cavity round-trip time, wherein a first of the plurality of the modified pump laser beam pulses is split into a first optical signal pulse at frequency ωₛ and a second optical signal pulse at frequency op;
receiving, by the interferometer, the first optical signal pulse at frequency ωₛ and reflects back through the first interferometer reflector the first optical signal pulse at frequency ωₛ that reaches an end of the optical parametric oscillator cavity at a reflector when the second optical signal pulse at frequency ωₛ has been sent to the sensor arm by an optical switch and reaches the second interferometer reflector;
receiving and detecting, by the first detector, the second optical signal pulse and to produce a synchronization signal for the optical switch;
amplifying and dividing by two, by the amplifier that is connected to the first detector, the synchronization signal and to produce an amplified detection signal to the optical switch and controlling operations of the optical switch based on the amplified detection signal; and
receiving and detecting, by the second detector, an optical path length change in the sensor arm of the interferometer as measured by a beat frequency produced by the interferometer.

16. The method of claim 15, wherein the second-harmonic generator and the optical parametric oscillator comprise periodically poled lithium niobate.

17. The method of claim 15, wherein the one or more layers comprise a silicon dioxide layer formed on a top surface of the substrate and a lithium niobate layer formed on a top surface of the silicon dioxide layer.

18. The method of claim 17, wherein the lithium niobate layer is x cut with a z axis perpendicular to a direction of propagation of first laser beam pulse and the second laser beam pulse through the first nonlinear optical parametric element and the second nonlinear optical parametric element.

19. The method of claim 17, wherein the pump laser beam is produced by a high frequency comb that is formed on the lithium niobate layer.

20. The method of claim 15, wherein the optical path length change is caused by a bend experienced by the substrate.
